(19) United States
(12) Patent Application Publication
(10) Pub. No.: US 2011/0068482 A1
(43) Pub. Date: Mar. 24, 2011

(54) SEMICONDUCTOR CHIP AND SEMICONDUCTOR DEVICE

(75) Inventor: Naoto AKIYAMA, Kanagawa (JP)

(73) Assignee: RENESAS ELECTRONICS CORPORATION, Kanagawa (JP)

(21) Appl. No.: 12/885,856

(22) Filed: Sep. 20, 2010

(30) Foreign Application Priority Data
Sep. 18, 2009 (JP) 2009-217167

(51) Int. Cl. H01L 23/48

(52) U.S. Cl. 257/778; 257/E23.01

(57) ABSTRACT

A semiconductor chip includes a plurality of electrode terminals having a fixed terminal which is supplied with a signal, an outside terminal for the signal being fixed when the semiconductor chip is mounted in both a face-up configuration and a face-down configuration on a package substrate that has the outside terminal, and which is arranged within 50% of the width of the semiconductor chip with a symmetric line of the semiconductor chip as a center. According to the present invention, it is possible to reduce the variation of the wiring delays of the fixed terminal and to keep the wiring routes from being complicated, when the semiconductor chip is mounted in both the face-up configuration and the face-down configuration.

### INCORPORATION BY REFERENCE

This application is based upon and claims the benefit of priority from Japanese patent application No. 2009-217167, filed on Sep. 18, 2009, the disclosure of which is incorporated herein in its entirety by reference.

### BACKGROUND

1. Field of the Invention

The present invention relates to a semiconductor chip and a semiconductor device having the semiconductor chip, and more particularly, to an arrangement of electrode terminals of the semiconductor chip.

2. Description of Related Art

In recent years, a technique for mounting a semiconductor chip on a package substrate has been developed. Japanese Unexamined Patent Application Publication No. 63-267598 discloses a technique for a semiconductor device allowing pad electrodes assigned to the same function to be connected to outside terminals of a mounting substrate in either one of a face-up configuration and a face-down configuration. Using the technique disclosed in Japanese Unexamined Patent Application Publication No. 63-267598, there is no need to separately prepare for the semiconductor chips that have the pad electrodes corresponding to both mounting methods of the face-up configuration and the face-down configuration. Further, it is possible to adapt to the many mounting methods by using only one semiconductor chip, while maintaining compatibility of the outside terminals. Note that the semiconductor chip is mounted in an inverted position with a symmetric line of the semiconductor chip as an axis, in both the face-up configuration and the face-down configuration.

That is, in the technique according to Japanese Unexamined Patent Application Publication No. 63-267598, each of a pad electrode for the face-up configuration and a pad electrode for the face-down configuration is prepared for one signal in the semiconductor chip, and each of the pad electrodes is electrically connected in the semiconductor chip. However, in this method, the double number of the pad electrodes is needed compared with the number of the pad electrodes necessary for one mounting method. Therefore, the area of the semiconductor chip and the cost of the semiconductor chip increase.

On the other hand, to solve the technical problems of Patent Application Publication No. 63-267598, Japanese Unexamined Patent Application Publication No. 11-67817 discloses a technique for a semiconductor memory, in which a group of pad electrodes for connecting the semiconductor memory to the outside and assigned to a plurality of same functions is arranged on a surface of a memory pellet (semiconductor chip) in both of the first and second quadrants divided by the center line of the memory pellet.

FIG. 13 is a top view of the memory pellet disclosed in Japanese

Unexamined Patent Application Publication No. 11-67817. As shown in FIG. 13, the memory pellet 110 includes a pad electrode A1 (111) for a function A, a pad electrode A2 (112) for the function A, a pad electrode B1 (113) for a function B, a pad electrode B2 (114) for the function B, a pad electrode C1 (117) for a function C, and a pad electrode C2 (118) for the function C. A center line 115 is the center line of the memory pellet 110, and the memory pellet 110 can be turned by 180 degrees about the center line 115 in the face-up configuration or in the face-down configuration. Lines 116 delimit a finite width defining the center line 115. As shown in FIG. 13, in the semiconductor memory disclosed in Japanese Unexamined Patent Application Publication No. 11-67817, the groups of pad electrodes 111, 112, 113, 114, 117 and 118 which connect the semiconductor memory to the outside and which are assigned to the plurality of same functions are arranged in both of the first and second quadrants divided by the center line 115 of the memory pellet 110.

FIG. 14A is a cross-section view in which the memory pellet 110 disclosed in Japanese Unexamined Patent Application Publication No. 11-67817 is mounted on the Ball Grid Array (BGA) package 126 in the face-up configuration. As shown in FIG. 14A, the pad electrode A1 (111) that is provided on an upper surface of the pellet 110 is connected to an internal wiring 122 of the BGA package substrate through a bonding wire 120. The pad electrode A2 (112) that is provided on the upper surface of the pellet 110 is connected to an internal wiring 123 of the BGA package substrate through a bonding wire 121. Each of the internal wirings 122 and 123 of the BGA package substrate is connected to balls 124 and 125 which are outside terminals of the BGA package substrate and which are corresponding to the pad electrode A1 (111) and A2 (112) for the function A. The memory pellet 110 is covered by a seal resin 127.

FIG. 14B is a cross-section view in which the memory pellet 110 disclosed in Japanese Unexamined Patent Application Publication No. 11-67817 is mounted on a Chip Size Package (CSP) substrate 146 in the face-down configuration. As shown in FIG. 14B, the pad electrode A1 (111) that is provided on an under surface of the pellet 110 is connected to an internal wiring 142 of the CSP substrate through a bump 140. The pad electrode A2 (112) that is provided on the under surface of the pellet 110 is connected to an internal wiring 143 of the CSP substrate through a bump 141. Each of the internal wirings 142 and 143 of the CSP substrate is connected to balls 144 and 145 which are outside terminals of the CSP substrate and which are corresponding to the pad electrode A1 (111) and A2 (112) for the function A. The surrounding area of the memory pellet 110 is covered by a seal resin 147.

Further, Japanese Unexamined Patent Application Publication No. 10-335587 discloses a technique for a semiconductor device including a circuit which is mounted on a semiconductor substrate and which outputs a plurality of normal or inverted signals. In the technique disclosed in Japanese Unexamined Patent Application Publication No. 10-335587, a plurality of wirings from outputs of the circuit on the semiconductor substrate to output terminals of a package are arranged nearly axisymmetric or point-symmetric about the package or the semiconductor substrate.

Further, Japanese Unexamined Patent Application Publication No. 2000-352723 discloses a technique for a semiconductor device that can achieve the homogenization of respective input or output characteristics by suppressing the variation in wiring impedance without broadening the wiring space, in an array structure in which circuit cells and input or output electrodes form pairs. Further, Japanese Unexamined Patent Application Publication No. 2007-12937 discloses a technique for a display driver that can maintain a signal quality in a high speed serial transfer.

### SUMMARY

As mentioned above, in the semiconductor chip disclosed in Japanese Unexamined Patent Application Publication No. 63-267598, each of the pad electrodes for the face-up configuration and the pad electrodes for the face-down configuration is prepared for one signal in the semiconductor chip. However, in this method, the double number of the pad electrodes is needed compared with the number of the pad electrodes necessary for one mounting method. Therefore, the present inventor has found a problem that the area of the semiconductor chip and the cost of the semiconductor chip increase.

Further, in the semiconductor chip disclosed in Japanese Unexamined Patent Application Publication No. 11-67817, the groups of pad electrodes for connecting the semiconductor memory to the outside and assigned to the plurality of same functions are arranged in both of the first and second quadrants divided by the center line of the memory pellet. That is, as shown in FIG. 13, the pad electrode A1 (111) for the function A and A2 (112) for the function A are arranged in both of the first and second quadrants divided by the center line of the memory pellet, for example. Note that the same function means a data input, a data output, an address signal input or the like.

Thus, because the pad electrodes which are connected to the outside and are assigned to the same functions are relatively major in the semiconductor memory, the pad electrodes which are assigned to the same functions can easily be arranged in both of the first and second quadrants. However, a semiconductor chip that has many signal lines such as a system LSI is different from the semiconductor memory and pad electrodes that are assigned to the same functions are not always exist. Further, even if a plurality of pad electrodes that are assigned to the same functions exist, the pad electrodes cannot always be arranged in both of the first and second quadrants.

On the other hand, it may be possible to share outside terminals of the package by separately designing the package substrate for the face-up configuration and the package substrate for the face-down configuration. However, the present inventor has found a problem that when the electrode terminals which are on the semiconductor chip and to which the outside terminals of the package are connected, are arranged at both sides of the semiconductor chip in which the sides are parallel to the symmetric line of the semiconductor chip, or are arranged at the positions extremely far from the symmetric line even on the sides of the semiconductor chip in which the sides are perpendicular to the symmetric line, it is difficult to design the package substrate so as to share the outside terminals of the package. Further, the present inventor has found a problem that the wiring in the package substrate becomes long and this influences on the variation of wiring delays.

A first exemplary aspect of the present invention is a semiconductor chip including a plurality of electrode terminals including a fixed terminal which is supplied with a signal, an outside terminal for the signal being fixed when the semiconductor chip is mounted in both a face-up configuration and a face-down configuration on a package substrate that has the outside terminal, and which is arranged within 50% of the width of the semiconductor chip with a symmetric line of the semiconductor chip as a center.

Thus, in the semiconductor chip according to the first exemplary aspect of the present invention, the fixed terminal is arranged within 50% of the width of the semiconductor chip with the symmetric line of the semiconductor chip as a center. Therefore, it is possible to reduce the variation of the wiring delays of the fixed terminal and to keep the wiring routes from being complicated, when the semiconductor chip is mounted in both the face-up configuration and the face-down configuration.

A second exemplary aspect of the present invention is a semiconductor device including the semiconductor chip according to the first exemplary aspect of the present invention; a package substrate on which the semiconductor chip is mounted and which includes a pad electrode to which the fixed terminal of the semiconductor chip is connected and the outside terminal to which the pad electrode is connected through an internal wiring.

Thus, in the semiconductor chip according to the first exemplary aspect of the present invention, the fixed terminal is arranged within 50% of the width of the semiconductor chip with a symmetric line of the semiconductor chip as a center. Therefore, it is possible to reduce the variation of the wiring delays of the fixed terminal and to keep the wiring routes from being complicated, when the semiconductor chip is mounted in both the face-up configuration and the face-down configuration.

According to the exemplary aspects of the present invention, it is possible to reduce the variation of the wiring delays of the fixed terminal and to keep the wiring routes from being complicated, when the semiconductor chip is mounted in both the face-up configuration and the face-down configuration.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a top view of a semiconductor chip according to a first exemplary embodiment;

FIG. 2A is a top view of a semiconductor device in which the semiconductor chip according to the first exemplary embodiment is mounted on a package substrate in a WB connection;

FIG. 2B is a top view of the semiconductor device in which the semiconductor chip according to the first exemplary embodiment is mounted on the package substrate in an FC connection;

FIG. 3A is a side view of the semiconductor device in which the semiconductor chip according to the first exemplary embodiment is mounted on the package substrate in the WB connection;

FIG. 3B is a side view of the semiconductor device in which the semiconductor chip according to the first exemplary embodiment is mounted on the package substrate in the FC connection;

FIG. 4A is a top view of a semiconductor device in which a semiconductor chip that is not applied the first exemplary embodiment is mounted on the package substrate in the WB connection;

FIG. 4B is a top view of the semiconductor device in which the semiconductor chip that is not applied the first exemplary embodiment is mounted on the package substrate in the FC connection;

FIG. 5A is a diagram illustrating a pitch of electrode terminals of the semiconductor chip according to the first exemplary embodiment and a pitch of pad electrodes of the package substrate, each of the electrode terminals and the pad electrodes is arranged in a row;

FIG. 5B is a diagram illustrating the pitch of the electrode terminals of the semiconductor chip according to the first exemplary embodiment and the pitch of the pad electrodes of the package substrate, each of the electrode terminals and the pad electrodes is arranged in a zigzag alignment;

FIG. 6 is a top view of the semiconductor device in which the semiconductor chip according to the first exemplary embodiment is mounted on the package substrate (the semiconductor chip is in a rectangle shape);

FIG. 7 is a top view of the semiconductor device in which the semiconductor chip according to the first exemplary embodiment is mounted on the package substrate (a diagonal line of the semiconductor chip is a symmetric line);

FIG. 8 is a top view of the semiconductor device in which the semiconductor chip according to the first exemplary embodiment is mounted on a package substrate (the semiconductor chip is in a rectangle shape and the diagonal line of the semiconductor chip is the symmetric line);

FIG. 9A is a top view of a semiconductor device in which a semiconductor chip according to a second exemplary embodiment is mounted on the package substrate in the WB connection and a memory chip is mounted on the semiconductor chip;

FIG. 9B is a top view of the semiconductor device in which the semiconductor chip according to the second exemplary embodiment is mounted on the package substrate in the FC connection and the memory chip is mounted on the semiconductor chip;

FIG. 10A is a side view of the semiconductor device in which the semiconductor chip according to the second exemplary embodiment is mounted on the package substrate in the WB connection and the memory chip is mounted on the semiconductor chip;

FIG. 10B is a side view of the semiconductor device in which the semiconductor chip according to the second exemplary embodiment is mounted on the package substrate in the FC connection and the memory chip is mounted on the semiconductor chip;

FIG. 11A is a side view of the semiconductor device in which the semiconductor chip according to the second exemplary embodiment is mounted on the package substrate in the WB connection and the memory chip is mounted on the semiconductor chip (an internal wiring of the package substrate is connected to an outside terminal);

FIG. 11B is a side view of the semiconductor device in which the semiconductor chip according to the second exemplary embodiment is mounted on the package substrate in the FC connection and the memory chip is mounted on the semiconductor chip;

FIG. 12A is a top view of a semiconductor device in which a semiconductor chip that is not applied the second exemplary embodiment is mounted on the package substrate in the WB connection and the memory chip is mounted on the semiconductor chip;

FIG. 12B is a top view of the semiconductor device in which the semiconductor chip that is not applied the second exemplary embodiment is mounted on the package substrate in the FC connection and the memory chip is mounted on the semiconductor chip; and

FIGS. 13 and 14 are diagrams illustrating the related arts.

### DETAILED DESCRIPTION OF THE EMPLARY EMBODIMENTS

### First Exemplary Embodiment

First exemplary embodiment of the present invention will be described below with reference to the accompanying drawings.

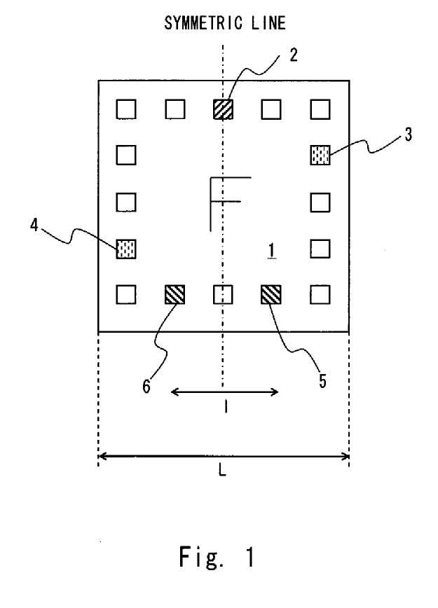

FIG. 1 is a top view of a semiconductor chip 1 according to this exemplary embodiment. The semiconductor chip 1 according to this exemplary embodiment is a system LSI or the like, for example. A fixed terminal 2 for an electrode terminal, arbitrary terminals 3 and 4, and replaceable terminals 5 and 6 are arranged on a surface of the semiconductor chip 1 and each of the terminals is connected to inner circuits of the semiconductor chip 1.

The fixed terminal 2 is supplied with a signal. An outside terminal for the signal is fixed when the semiconductor chip 1 is mounted in both a face-up configuration and a face-down configuration on a package substrate that has the outside terminal (ball). For example, the fixed terminal 2 is a terminal for a high speed signal, a terminal for a control signal, a terminal the location of which is fixed on a socket or the like. That is, the fixed terminal 2 is a terminal that should be preferentially arranged on considering an electrical property of the signal or a convenience of a measurement. Further, the arbitrary terminals 3 and 4 are the terminals, in which the outside terminals that are corresponding to the arbitrary terminals 3 and 4 are not fixed, and that is GV, NC or the like, for example. Further, the replaceable terminals 5 and 6 are the terminals that do not substantively influence on an operation of the semiconductor chip 1, even if the outside terminals are replaced each other when the semiconductor chip is mounted on the package substrate in both the face-up configuration and the face-down configuration. For example, the replaceable terminals 5 and 6 are terminals for a data output, a data input, the same kind of power sources or the like.

In the semiconductor chip 1 according to this exemplary embodiment, the fixed terminal 2 is arranged within 50% (within the width 1 in FIG. 1) of the width L of the semiconductor chip, preferably within 20% of the width L of the semiconductor chip, more preferably within 10% of the width L of the semiconductor chip, with a symmetric line of the semiconductor chip 1 as a center. By arranging the fixed terminal as mentioned above, it is possible to arrange the fixed terminal within a definite area from the symmetric line of the semiconductor chip 1 when the semiconductor chip 1 is mounted in both the face-up configuration (it is also described as Wire Bounding (WB) connection, hereinafter) and in the face-down configuration (it is also described as Flip-Chip (FC) connection, hereinafter). Therefore, it is possible to reduce the variation of the wiring delays of the fixed terminal and to keep the wiring routes from being complicated, when the semiconductor chip is mounted in both the face-up configuration and the face-down configuration.

Further, in the semiconductor chip 1 according to this exemplary embodiment, the replaceable terminals 5 and 6 are arranged at symmetrical positions with the symmetric line of the semiconductor chip as a center. By arranging the replaceable terminals as mentioned above, the semiconductor chip 1 can perform the same operation when the semiconductor chip 1 is mounted in both the face-up configuration (i.e., WB connection) and the face-down configuration (i.e., FC connection). Further, the arbitrary terminals 3 and 4 can be connected to any terminals when the semiconductor chip 1 is mounted in both the face-up configuration (i.e., WB connection) and the face-down configuration (i.e., FC connection). Hereinafter, the invention according to this exemplary embodiment is explained in detail.

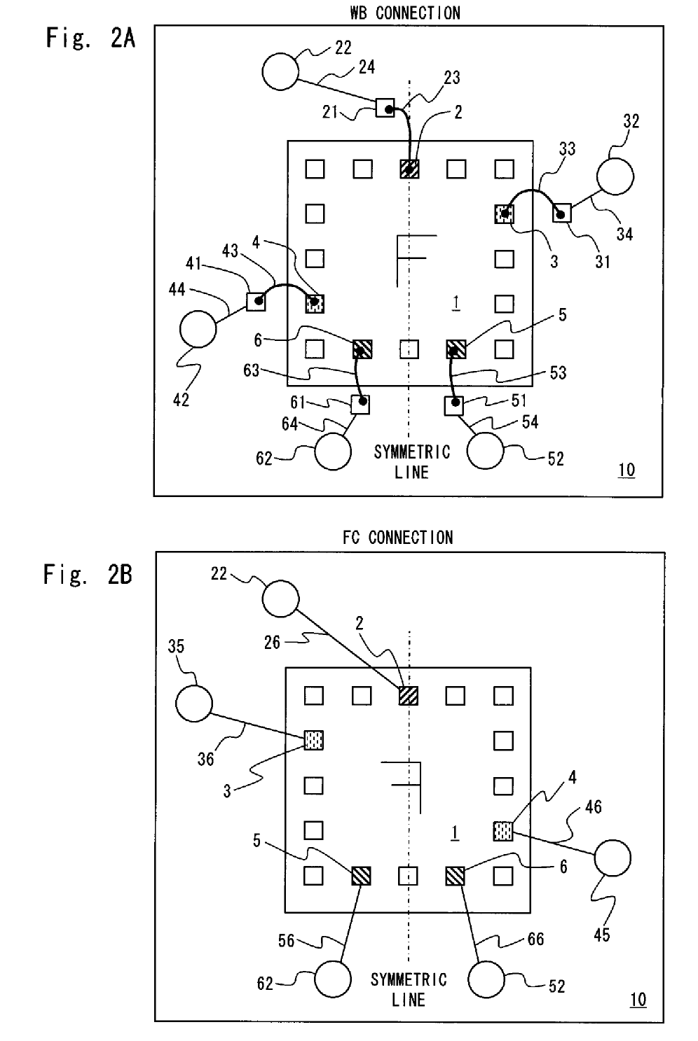

FIGS. 2A and 2B are top views of a semiconductor device in which the semiconductor chip 1 according to the first exemplary embodiment is mounted on a package substrate 10. As shown in FIGS. 2A and 2B, the semiconductor chip 1 is mounted on the package substrate 10. At first, the configuration of FIG. 2A, that is the semiconductor device in which the semiconductor chip 1 is mounted on a package substrate 10 in the WB connection is explained. As shown in FIG. 2A, the fixed terminal 2 of the semiconductor chip 1 is connected to a pad electrode 21 on the package substrate 10 through a bonding wire 23. The pad electrode 21 is connected to an outside terminal (ball) 22 through an internal wiring 24 in the package substrate 10. The pad electrode 21 can be arranged near the symmetric line of the semiconductor chip 1. Note that the pad electrode 21 may be arranged on the symmetric line of the semiconductor chip 1.

Further, the arbitrary terminal 3 of the semiconductor chip 1 is connected to a pad electrode 31 on the package substrate 10 through a bonding wire 33. The pad electrode 31 is connected to an outside terminal (ball) 32 through an internal wiring 34 in the package substrate 10. Similarly, the arbitrary terminal 4 of the semiconductor chip 1 is connected to a pad electrode 41 on the package substrate 10 through a bonding wire 43. The pad electrode 41 is connected to an outside terminal (ball) 42 through an internal wiring 44 in the package substrate 10.

Further, the replaceable terminal 5 of the semiconductor chip 1 is connected to a pad electrode 51 on the package substrate 10 through a bonding wire 53. The pad electrode 51 is connected to an outside terminal (ball) 52 through an internal wiring 54 in the package substrate 10. Similarly, the replaceable terminal 6 of the semiconductor chip 1 is connected to a pad electrode 61 on the package substrate 10 through a bonding wire 63. The pad electrode 61 is connected to an outside terminal (ball) 62 through an internal wiring 64 in the package substrate 10.

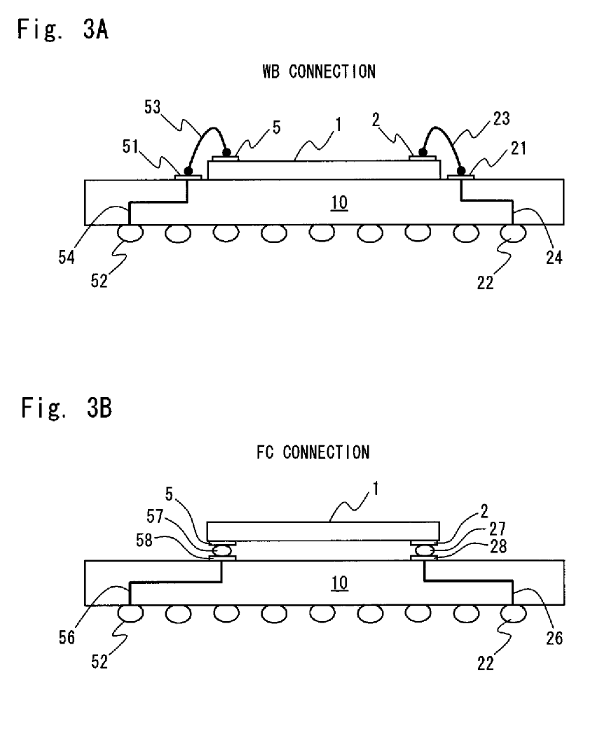

FIG. 3A is a side view when the semiconductor chip 1 and the package substrate 10 shown in FIG. 2A are viewed from the right side of the document. As a matter of convenience, each of connecting relationships of the fixed terminal 2 and the replaceable terminal 5 is shown in FIG. 3A. As shown in FIG. 3A, the semiconductor chip 1 is mounted on the package substrate 10. The fixed terminal 2 of the semiconductor chip 1 is connected to the pad electrode 21 on the package substrate 10 through the bonding wire 23. The pad electrode 21 is connected to the outside terminal 22 through the internal wiring 24 in the package substrate 10. The replaceable terminal 5 of the semiconductor chip 1 is connected to the pad electrode 51 on the package substrate 10 through the bonding wire 53. The pad electrode 51 is connected to the outside terminal 52 through the internal wiring 54 in the package substrate 10.

Next, the semiconductor device in which the semiconductor chip 1 is mounted on the package substrate 10 in the FC connection. Note that, in FIG. 2B, the fixed terminal 2, the arbitrary terminals 3 and 4, and the replaceable terminals 5 and 6 are reversely arranged with respect to the WB connection. As shown in FIG. 2B, the fixed terminal 2 of the semiconductor chip 1 is connected to an outside terminal 22 through an internal wiring 26 of the package substrate 10. The arbitrary terminal 3 of the semiconductor chip 1 is connected to an outside terminal 35 through an internal wiring 36 of the package substrate 10. The arbitrary terminal 4 of the semiconductor chip 1 is connected to an outside terminal 45 through an internal wiring 46 of the package substrate 10. The replaceable terminal 5 is connected to an outside terminal 62 through an internal wiring 56 of the package substrate 10. The replaceable terminal 6 is connected to an outside terminal 52 through an internal wiring 66 of the package substrate 10. Note that, each of the terminals 2, 3, 4, 5 and 6 and each of pad electrodes (not shown) on the package substrate 10, to which the internal wirings 26, 36, 46, 56 and 66 are connected, are connected through bumps (not shown) in the FC connection.

FIG. 3B is a side view when the semiconductor chip 1 and the package substrate 10 shown in FIG. 2B are viewed from the right side of the document. As a matter of convenience, each of connecting relationships of the fixed terminal 2 and the replaceable terminal 5 is shown in FIG. 3B. As shown in FIG. 3B, the semiconductor chip 1 is mounted on the package substrate 10 through bumps 27, 57. The fixed terminal 2 is connected to a pad electrode 28 on the package substrate 10 through the bump 27. The pad electrode 28 is connected to the outside terminal 22 through the internal wiring 26 in the package substrate 10. In this case, the pad electrode 28 is arranged at a position corresponding to a position of the fixed terminal 2 of the semiconductor chip 1, that is, at a position facing to the fixed terminal 2. The replaceable terminal 5 is connected to a pad electrode 58 on the package substrate 10 through the bump 57. The pad electrode 58 is connected to the outside terminal 52 through the internal wiring 56 in the package substrate 10.

When the face-up configuration (WB connection, shown in FIG. 2A) is compared with the face-down configuration (FC connection, shown in FIG. 2B), the fixed terminal 2 is connected to the outside terminal 22 in both the WB connection and the FC connection, and the outside terminals the fixed terminal 2 connect thereto do not change in accordance with the difference between the WB connection and the FC connection. That is, the fixed terminal is connected to the same outside terminal of the package substrate in both the WB connection and the FC connection.

On the other hand, the arbitrary terminal 3 is connected to the outside terminal 32 in the WB connection. The arbitrary terminal 3 is connected to the outside terminal 35 in the FC connection. Further, the arbitrary terminal 4 is connected to the outside terminal 42 in the WB connection. The arbitrary terminal 4 is connected to the outside terminal 45 in the FC connection. Thus, in the case of the arbitrary terminals, it is possible to change the outside terminals the arbitrary terminals connect thereto in accordance with the WB connection and the FC connection.

Further, the replaceable terminal 5 is connected to the outside terminal 52 in the WB connection. The replaceable terminal 5 is connected to the outside terminal 62 in the FC connection. Further, the replaceable terminal 6 is connected to the outside terminal 62 in the WB connection. The replaceable terminal 6 is connected to the outside terminal 52 in the FC connection. That is, in the case of the replaceable terminals, the outside terminal 52 and 62 the replaceable terminals connect thereto are replaced each other in accordance with the WB connection and the FC connection.

As mentioned above, the fixed terminal 2 can be arranged on the symmetric line of the semiconductor chip 1 in both the WB connection and the FC connection of the semiconductor chip 1 by arranging the fixed terminal 2 on the symmetric line of the semiconductor chip 1. Therefore, this makes it possible to reduce the variation of the wiring delays of the fixed terminal 2 and to keep the wiring routes from being complicated, when the semiconductor chip is mounted in both the face-up configuration (i.e., WB connection) and the face-down configuration (i.e., FC connection).

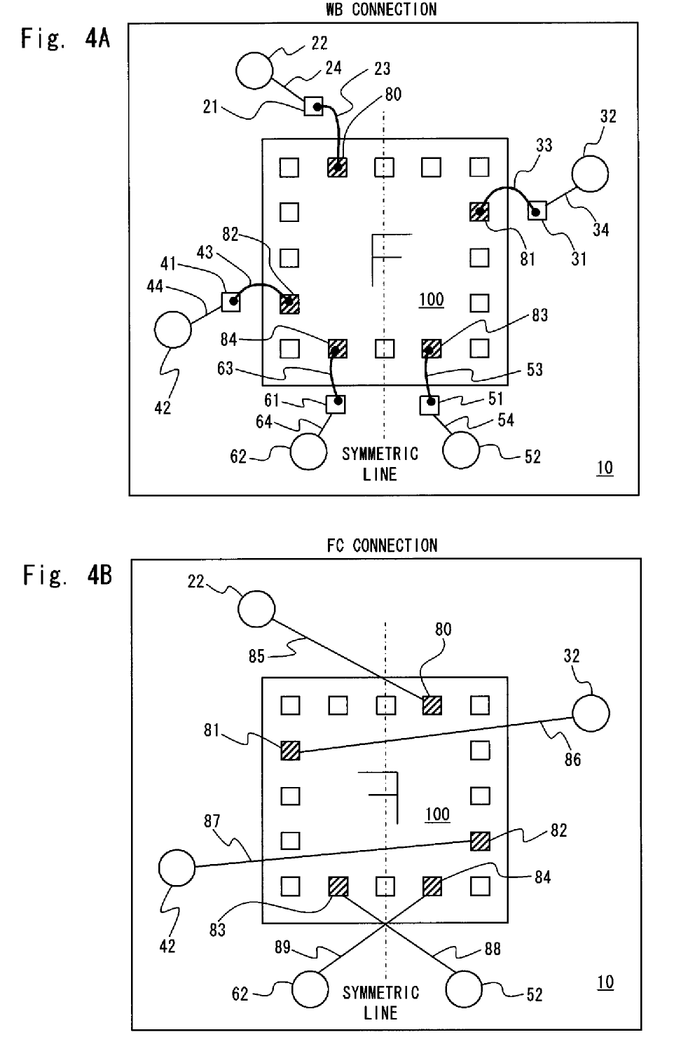

Next, as a comparative example, a semiconductor device in which a semiconductor chip that is not applied this exemplary embodiment is mounted on the package substrate is described with reference to FIGS. 4A and 4B. First, a configuration in which a semiconductor chip 100 is mounted on the package substrate 10 in the WB connection is described with reference to FIG. 4A. As shown in FIG. 4A, fixed terminals 80, 81, 82, 83 and 84 are arranged in some part other than the symmetric line of the semiconductor chip 100, on a surface of a semiconductor chip 100 that is not applied this exemplary embodiment. The fixed terminal 80 of the semiconductor chip 100 is connected to the pad electrode 21 on the package substrate 10 through the bonding wire 23. The pad electrode 21 is connected to the outside terminal 22 through the internal wiring 24 in the package substrate 10.

The fixed terminal 81 is connected to the pad electrode 31 on the package substrate 10 through the bonding wire 33. The pad electrode 31 is connected to the outside terminal 32 through the internal wiring 34 in the package substrate 10. The fixed terminal 82 is connected to the pad electrode 41 on the package substrate 10 through the bonding wire 43. The pad electrode 41 is connected to the outside terminal 42 through the internal wiring 44 in the package substrate 10.

The fixed terminal 83 is connected to the pad electrode 51 on the package substrate 10 through the bonding wire 53. The pad electrode 51 is connected to the outside terminal 52 through the internal wiring 54 in the package substrate 10. The fixed terminal 84 is connected to the pad electrode 61 on the package substrate 10 through the bonding wire 63. The pad electrode 61 is connected to the outside terminal 62 through the internal wiring 64 in the package substrate 10.

Next, a configuration in which the semiconductor chip 100 is mounted on the package substrate 10 in the FC connection is described with reference to FIG. 4B. The fixed terminals 80, 81, 82, 83 and 84 provided on the semiconductor chip 100 should also be connected to the outside terminals 22, 32, 42, 52 and 62, respectively, in the FC connection. Therefore, as shown in FIG. 4B, the fixed terminal 80 is connected to the outside terminal 22 through an internal wiring 85. The fixed terminal 81 is connected to the outside terminal 32 through an internal wiring 86. The fixed terminal 82 is connected to the outside terminal 42 through an internal wiring 87. The fixed terminal 83 is connected to the outside terminal 52 through an internal wiring 88. The fixed terminal 84 is connected to the outside terminal 62 through an internal wiring 89. Note that, each of the fixed terminals 80, 81, 82, 83 and 84 and each of pad electrodes (not shown) on the package substrate 10, to which the internal wirings 85, 86, 87, 88 and 89 are connected, are connected through bumps (not shown) in the FC connection.

As described above, the wiring routes of the internal wiring 85, 86, 87, 88 and 89 of the package substrate 10 become complicated when the fixed terminals that are provided on the semiconductor chip 100 are arranged in some part other than the symmetric line of the semiconductor chip 100. Further, because the difference between the wiring length from the fixed terminal to the outside terminal in the WB connection and the wiring length from the fixed terminal to the outside terminal in the FC connection increases, the difference between the wiring delay in the WB connection and the wiring delay in the FC connection increases.

On the other hand, as shown in FIGS. 2A and 2B, when the fixed terminal is arranged on the symmetric line of the semiconductor chip 1, the wiring routes in the WB connection and the FC connection do not become complicated. That is, when the connection of the fixed terminal 2 and the outside terminal 22 in the WB connection shown in FIG. 2A is compared with the connection of the fixed terminal 2 and the outside terminal 22 in the FC connection shown in FIG. 2B, both of the wiring routes are simple. Further, it is possible to reduce the difference between the wiring length from the fixed terminal 2 to the outside terminal 22 in the WB connection and the wiring length from the fixed terminal 2 to the outside terminal 22 in the FC connection. Therefore, this makes it possible to reduce the difference between the wiring delay in the WB connection and the wiring delay in the FC connection.

In FIGS. 2 and 3, the case in which the fixed terminal is arranged on the symmetric line of the semiconductor chip 1 is described. However, the fixed terminal 2 may be arranged within 50% of the width of the semiconductor chip (within the width 1 in FIG. 1, i.e., within 25% of one side), preferably within 20% of the width of the semiconductor chip (i.e., within 10% of one side), more preferably within 10% of the width of the semiconductor chip (i.e., within 5% of one side), with the symmetric line of the semiconductor chip as a center. In this exemplary embodiment, the advantageous effects of the invention become more apparent, as the position where the fixed terminal 2 is arranged is closer to the symmetric line.

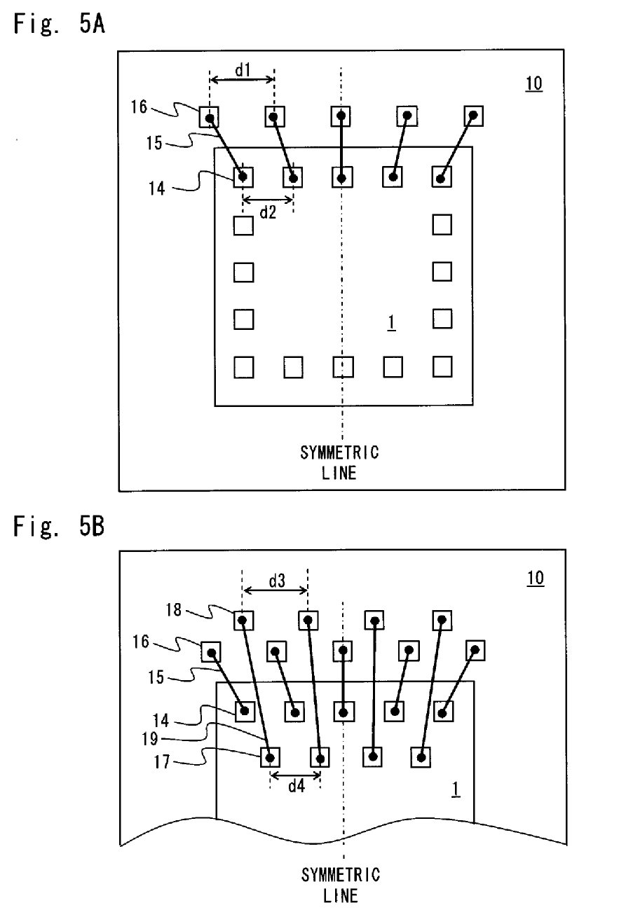

FIG. 5A is a diagram illustrating a pitch of electrode terminals 14 on the semiconductor chip 1 and a pitch of pad electrodes 16 on the package substrate 10. Each of the electrode terminals 14 on the semiconductor chip 1 and each of the pad electrodes 16 on the package substrate 10 are connected through each of bonding wires 15. As shown in FIG. 5A, assuming that a minimum pitch of the pad electrode 16 on the package substrate 10 is d1, the fixed terminal 2 may be arranged within about twenty times of d1 (i.e., within ten times of d1 in one side) with the symmetric line of the semiconductor chip as a center. Further, as shown in FIG. 5A, assuming that a minimum pitch of the electrode terminal 14 on the semiconductor chip 1 is d2, the fixed terminal 2 may be arranged within about twenty times of d2 (i.e., within ten times of d2 in one side) with the symmetric line of the semiconductor chip as a center.

FIG. 5B is a diagram illustrating the pitch of the electrode terminals 14, 17 of the semiconductor chip 1 and the pitch of the pad electrodes 16, 18 of the package substrate 10, each of the electrode terminals 14 and 17 and the pad electrodes 16 and 18 is arranged in a zigzag alignment. Each of the electrode terminals 14 on the semiconductor chip 1 and each of the pad electrodes 16 on the package substrate 10 are connected through each of bonding wires 15. Further, each of the electrode terminals 17 on the semiconductor chip 1 and each of the pad electrodes 18 on the package substrate 10 are connected through each of bonding wires 19.

As shown in FIG. 5B, assuming that a minimum pitch of the pad electrode 18 that is arranged in zigzag on the package substrate 10 is d3, the fixed terminal 2 may be arranged within about twenty times of d3 (i.e., within ten times of d3 in one side) with the symmetric line of the semiconductor chip as a center. Further, as shown in FIG. 5B, assuming that a minimum pitch of the pad electrode 14 that is arranged in zigzag on the semiconductor chip 1 is d4, the fixed terminal 2 may be arranged within about twenty times of d4 (i.e., within ten times of d4 in one side) with the symmetric line of the semiconductor chip as a center.

Note that, in FIGS. 5A and 5B, the ratio of each of the minimum pitch d2 of the electrode terminals 14, the minimum pitch d4 of the electrode terminals 17, the minimum pitch d1 of the pad electrodes 16, and the minimum pitch d3 of the pad electrodes 18 to the width of the semiconductor chip 1 is illustrated larger than that in actual, as a matter of convenience. Actually, the values d1, d2, d3 and d4 are small enough compared with the width of the semiconductor chip 1.

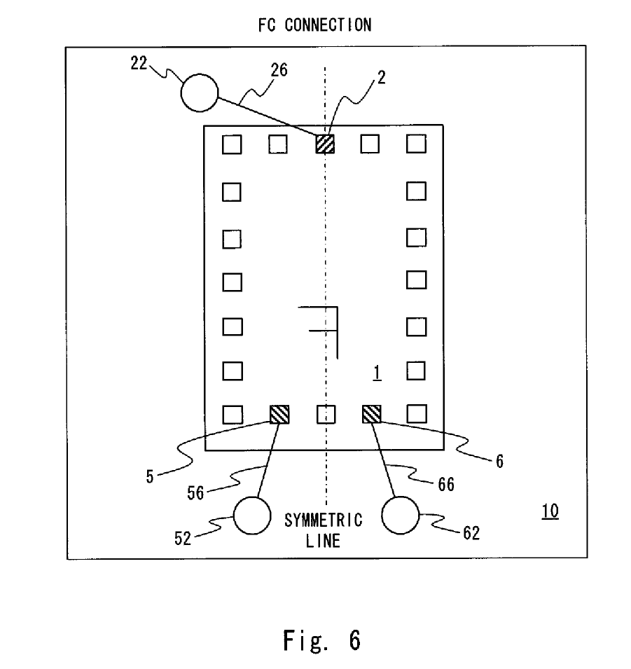

Further, as shown in FIG. 6, the semiconductor chip 1 may be a rectangle shape in this exemplary embodiment. As for the position of the fixed terminal 2, the configuration is the same as mentioned above.

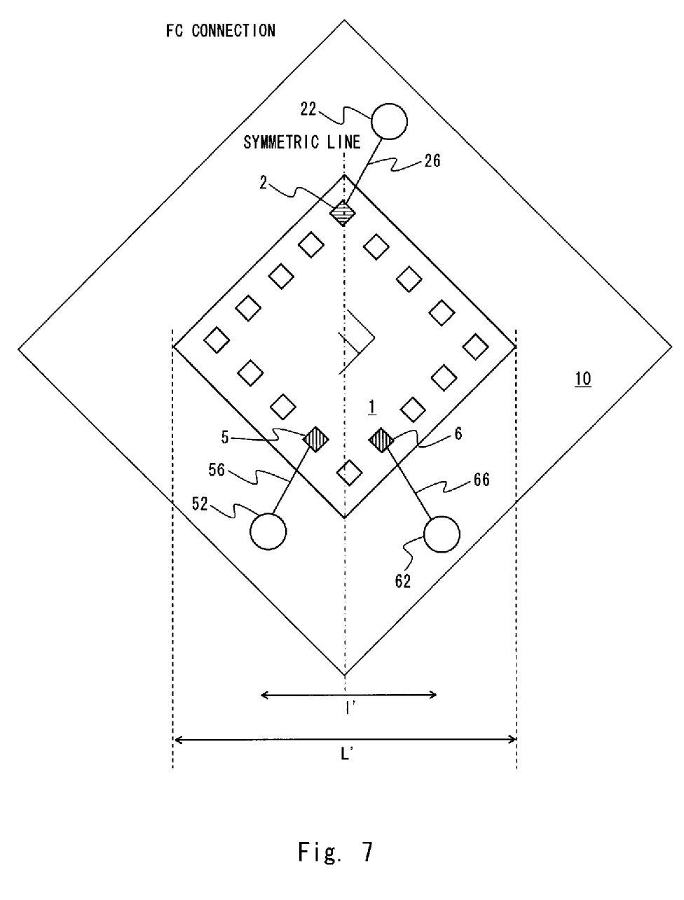

Further, as shown in FIG. 7, the fixed terminal 2 may be arranged on the symmetric line which is a diagonal line of the semiconductor chip 1 in this exemplary embodiment. In this case, the replaceable terminals 5 and 6 can be arranged at symmetrical positions with the diagonal line of the semiconductor chip 1 as a center. The fixed terminal 2 may also be arranged within 50% of the width L′ of the semiconductor chip (within the width 1′ in FIG. 7, i.e., within 25% of one side), preferably within 20% of the width L′ of the semiconductor chip (i.e., within 10% of one side), more preferably within 10% of the width L′ of the semiconductor chip (i.e., within 5% of one side), with the symmetric line of the semiconductor chip as a center.

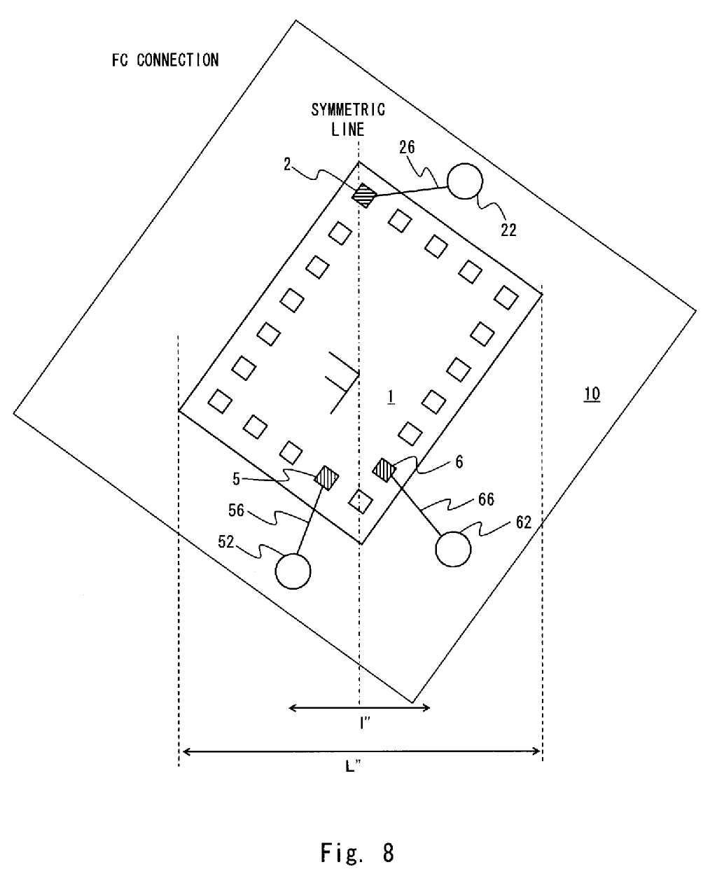

Further, as shown in FIG. 8, the fixed terminal 2 may be arranged on the symmetric line which is a diagonal line of the semiconductor chip 1 which has the rectangle shape in this exemplary embodiment. In this case, the replaceable terminals 5 and 6 can be arranged at symmetrical positions with the diagonal line of the semiconductor chip 1 as a center. The fixed terminal 2 may also be arranged within 50% of the width L″ of the semiconductor chip (within the width 1″ in FIG. 8, i.e., within 25% of one side), preferably within 20% of the width L″ of the semiconductor chip (i.e., within 10% of one side), more preferably within 10% of the width L″ of the semiconductor chip (i.e., within 5% of one side), with the symmetric line of the semiconductor chip as a center.

In this exemplary embodiment, the replaceable terminals may be arranged on a side of the semiconductor chip, the side is vertical to the symmetric line of the semiconductor chip. Further, the replaceable terminals may be arranged at the vicinity of the symmetric line of the semiconductor chip. The vicinity of the symmetric line is within 50% of the width of the semiconductor chip (i.e., within 25% of one side), preferably within 20% of the width of the semiconductor chip (i.e., within 10% of one side), more preferably within 10% of the width of the semiconductor chip (i.e., within 5% of one side), with the symmetric line of the semiconductor chip as a center. In this case, the replaceable terminals may only be arranged at one side of the area divided by the symmetric line.

As mentioned above, in this exemplary embodiment, the fixed terminal is arranged within 50% of the width of the semiconductor chip with the symmetric line of the semiconductor chip as a center. Therefore, it is possible to reduce the variation of the wiring delays of the fixed terminal and to keep the wiring routes from being complicated, when the semiconductor chip is mounted in both the face-up configuration (i.e., WB connection) and the face-down configuration (i.e., FC connection).

### Second Exemplary Embodiment

Second exemplary embodiment of the present invention will be described below with reference to the accompanying drawings.

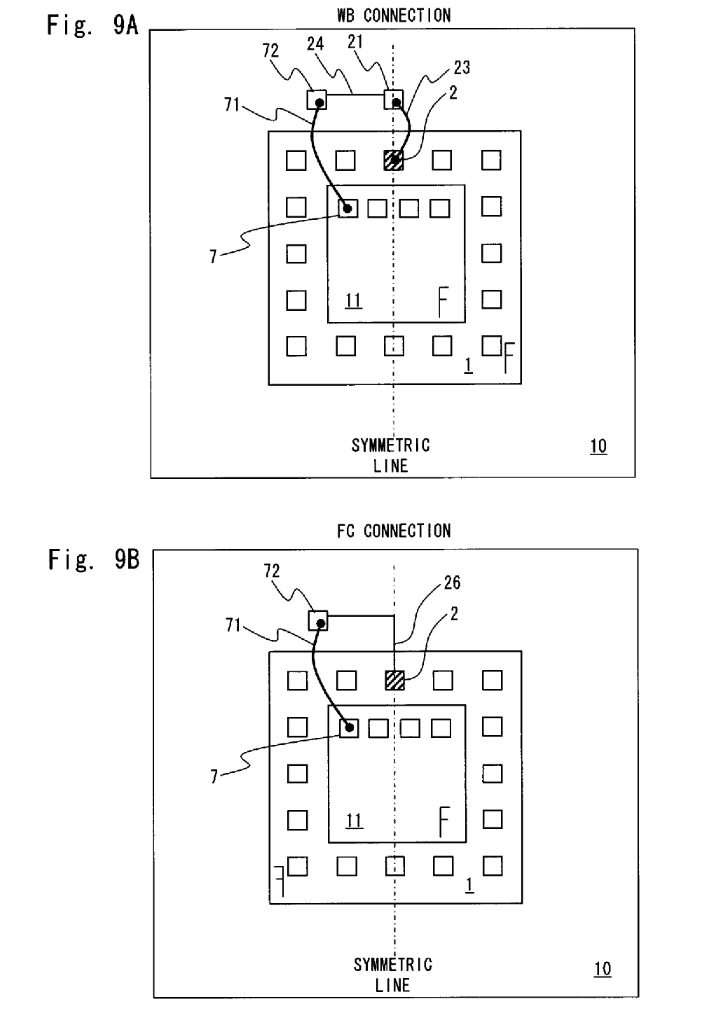

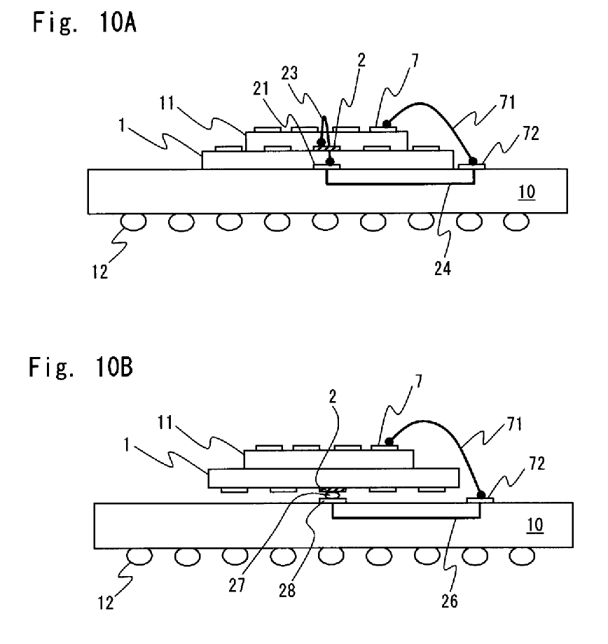

FIGS. 9A and 9B are top views of a semiconductor device in which a semiconductor chip 1 according to this exemplary embodiment is mounted on the package substrate, and a memory chip 11 is mounted on the semiconductor chip 1. FIG. 9A illustrates the case in which the semiconductor chip 1 is mounted on the package substrate 10 in the WB connection. FIG. 9B illustrates the case in which the semiconductor chip 1 is mounted on the package substrate 10 in the FC connection. FIG. 10A is a side view when the semiconductor device shown in FIG. 9A is viewed from the upper side of the document. FIG. 10B is a side view when the semiconductor device shown in FIG. 9B is viewed from the upper side of the document.

First, the case in which the semiconductor chip 1 is mounted on the package substrate 10 in the WB connection is described with reference to FIGS. 9A and 10A. As shown in FIGS. 9A and 10A, the fixed terminal 2 on the semiconductor chip 1 and an electrode terminal 7 on the memory chip 11 are connected through the package substrate 10. That is, the fixed terminal 2 on the semiconductor chip 1 is connected to the pad electrode 21 on the package substrate 10 through the bonding wire 23. The electrode terminal 7 on the memory chip 11 is connected to a pad electrode 72 on the package substrate 10 through a bonding wire 71. Further, the pad electrode 21 on the package substrate 10 and the pad electrode 72 are connected through the internal wiring 24 in the package substrate 10. Note that, a plurality of outside terminals 12 are provided on the package substrate 10.

Next, the case in which the semiconductor chip 1 is mounted on the package substrate 10 in the FC connection is described with reference to FIGS. 9B and 10B. As shown in FIGS. 9B and 10B, the fixed terminal 2 on the semiconductor chip 1 and the electrode terminal 7 on the memory chip 11 are connected through the package substrate 10. That is, the fixed terminal 2 on the semiconductor chip 1 is connected to the pad electrode 28 on the package substrate 10 through the bump 27 (see FIG. 10B). The electrode terminal 7 on the memory chip 11 is connected to the pad electrode 72 on the package substrate 10 through the bonding wire 71. Further, the pad electrode 28 on the package substrate 10 and the pad electrode 72 are connected through the internal wiring 26 in the package substrate 10. Note that, the plurality of outside terminals 12 are provided on the package substrate 10.

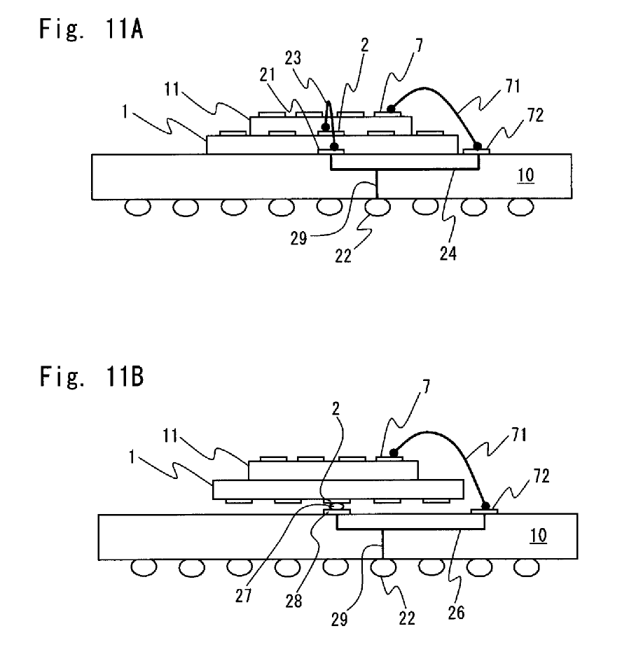

Note that, as shown in FIGS. 11A and 11B, each of the internal wirings 24 and 26 may be connected to the outside terminal 22 through an internal wiring 29 in the semiconductor device according to this exemplary embodiment. This configuration makes it possible to connect the fixed terminal 2 on the semiconductor chip 1 and the electrode terminal 7 on the memory chip 11 with the outside terminal 22.

As mentioned above, the fixed terminal 2 can be arranged on the symmetric line of the semiconductor chip 1 in both the WB connection and the FC connection of the semiconductor chip 1 by arranging the fixed terminal 2 on the symmetric line of the semiconductor chip 1. Therefore, this makes it possible to reduce the variation of the wiring delays of the fixed terminal 2 and to keep the wiring routes from being complicated, when the semiconductor chip is mounted in both the face-up configuration (i.e., WB connection) and the face-down configuration (i.e., FC connection).

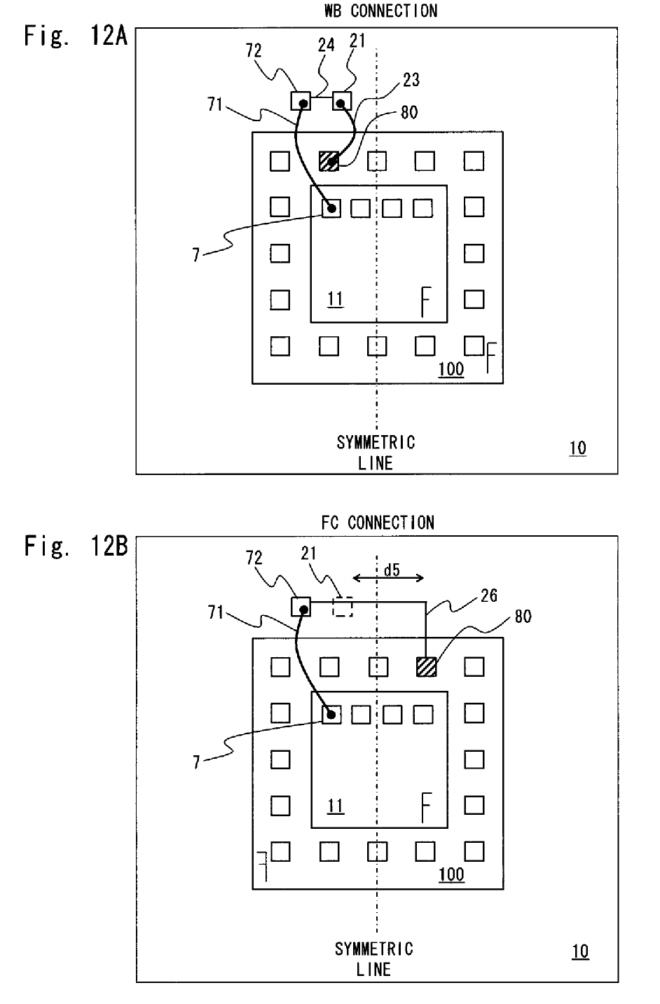

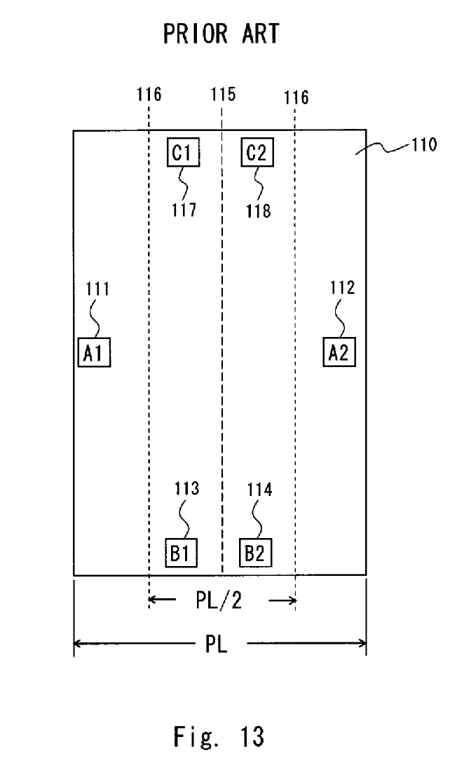

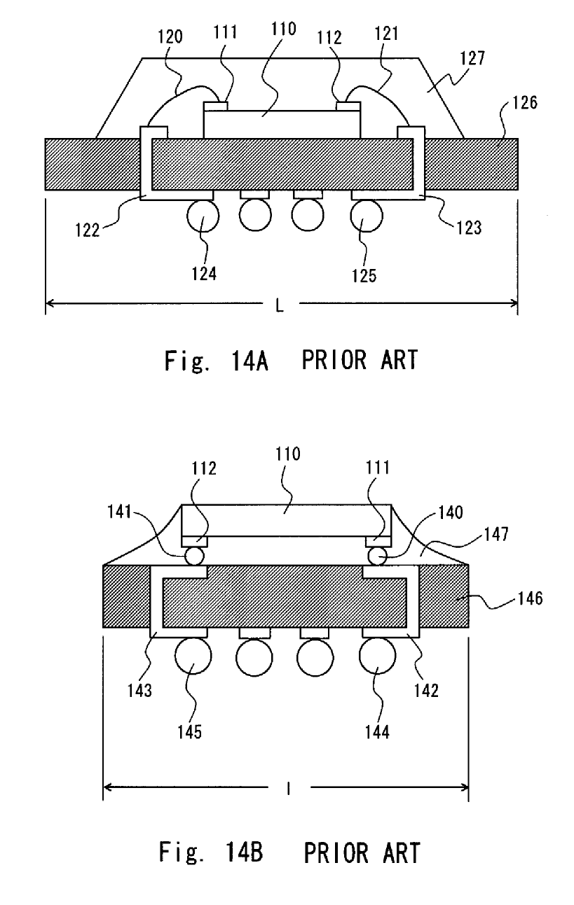

Next, as a comparative example, a semiconductor device in which a semiconductor chip that is not applied this exemplary embodiment is mounted on the package substrate is described with reference to FIGS. 12A and 12B. First, a configuration in which the semiconductor chip 100 is mounted on the package substrate 10 in the WB connection is described with reference to FIG. 12A. As shown in FIG. 12A, the fixed terminal 80 is arranged in some part other than the symmetric line of the semiconductor chip 100, on the surface of the semiconductor chip 100 that is not applied this exemplary embodiment. The fixed terminal 80 of the semiconductor chip 100 is connected to the pad electrode 21 on the package substrate 10 through the bonding wire 23. The electrode terminal 7 on the memory chip 11 is connected to the pad electrode 72 on the package substrate 10 through the bonding wire 71. Further, the pad electrode 21 on the package substrate 10 is connected to the pad electrode 72 through the internal wiring 24 in the package substrate 10.

Next, a configuration in which the semiconductor chip 100 is mounted on the package substrate 10 in the FC connection is described with reference to FIG. 12B. As shown in FIG. 12B, in the FC connection, the fixed terminal 80 on the semiconductor chip 100 is arranged at a symmetrical position of the WB connection with the symmetrical line as a center. In this case, the fixed terminal 80 is also arranged in some part other than the symmetric line of the semiconductor chip 100. As is the case in FIGS. 9B and 10B, the fixed terminal 80 on the semiconductor chip 100 is connected to the pad electrode on the package substrate 10 through the bump. This pad electrode on the package substrate 10 is connected to the pad electrode 72 on the package substrate 10 through the internal wiring 26. The electrode terminal 7 on the memory chip 11 is connected to the pad electrode 72 on the package substrate 10 through the bonding wire 71.

As shown in FIGS. 12A and 12B, when the fixed terminal 80 that is provided on the surface of the semiconductor chip 100 is arranged in some part other than the symmetric line of the semiconductor chip 100, a length of the internal wiring 26 in the FC connection (shown in FIG. 12B) increases by about a length d5 shown in FIG. 12B, compared with a length of the internal wiring 24 in the WB connection (shown in FIG. 12A). That is, when the fixed terminal 80 is arranged in some part other than the symmetric line of the semiconductor chip 100, the length of the internal wiring 24 in the WB connection and the length of the internal wiring 26 in the FC connection are different from each other, and the wiring delays thereof are also different from each other.

On the other hand, as shown in FIGS. 9A and 9B, when the fixed terminal 2 is arranged on the symmetric line of the semiconductor chip 1, it is possible to reduce the difference between the wiring length from the fixed terminal 2 to the pad electrode 72 in the WB connection and the wiring length from the fixed terminal 2 to the pad electrode 72 in the FC connection. Therefore, this makes it possible to reduce the difference between the wiring delay in the WB connection and the wiring delay in the FC connection. Further, it is possible to keep the wiring routes in the WB connection and the wiring routes in the FC connection from being complicated, by arranging the fixed terminal 2 on the symmetric line of the semiconductor chip 1.

In FIGS. 9 and 10, the case in which the fixed terminal is arranged on the symmetric line of the semiconductor chip 1 is described. However, the fixed terminal 2 may be arranged within 50% of the width L of the semiconductor chip (within the width 1 in FIG. 1, i.e., within 25% of one side), preferably within 20% of the width L of the semiconductor chip (i.e., within 10% of one side), more preferably within 10% of the width L of the semiconductor chip (i.e., within 5% of one side), with the symmetric line of the semiconductor chip as a center.

Further, as is the case in the first exemplary embodiment, the fixed terminal 2 may also be arranged as mentioned below in this exemplary embodiment. That is, as shown in FIG. 5A, assuming that the minimum pitch of the pad electrode 16 on the package substrate 10 is d1, the fixed terminal 2 may be arranged within about twenty times of d1 (i.e., within ten times of d1 in one side) with the symmetric line of the semiconductor chip as a center. Further, as shown in FIG. 5A, assuming that the minimum pitch of the electrode terminal 14 on the semiconductor chip 1 is d2, the fixed terminal 2 may be arranged within about twenty times of d2 (i.e., within ten times of d2 in one side) with the symmetric line of the semiconductor chip as a center.

As shown in FIG. 5B, assuming that the minimum pitch of the pad electrode 18 that is arranged in zigzag on the package substrate 10 is d3, the fixed terminal 2 may be arranged within about twenty times of d3 (i.e., within ten times of d3 in one side) with the symmetric line of the semiconductor chip as a center. Further, as shown in FIG. 5B, assuming that the minimum pitch of the pad electrode 14 that is arranged in zigzag on the semiconductor chip 1 is d4, the fixed terminal 2 may be arranged within about twenty times of d4 (i.e., within ten times of d4 in one side) with the symmetric line of the semiconductor chip as a center.

Further, as is the case in the first exemplary embodiment, the semiconductor chip 1 may be the rectangle shape, as shown in FIG. 6, in this exemplary embodiment. As for the position of the fixed terminal 2, the configuration is the same as mentioned above.

Further, as is the case in the first exemplary embodiment, the fixed terminal 2 may be arranged on the symmetric line which is a diagonal line of the semiconductor chip 1, as shown in FIG. 7, in this exemplary embodiment. In this case, the fixed terminal 2 may also be arranged within 50% of the width L′ of the semiconductor chip (within the width 1′ in FIG. 7, i.e., within 25% of one side), preferably within 20% of the width L′ of the semiconductor chip (i.e., within 10% of one side), more preferably within 10% of the width L′ of the semiconductor chip (i.e., within 5% of one side), with the symmetric line of the semiconductor chip as a center.

Further, as is the case in the first exemplary embodiment, the fixed terminal 2 may be arranged on the symmetric line which is a diagonal line of the semiconductor chip 1 which has the rectangle shape, as shown in FIG. 8, in this exemplary embodiment. In this case, the fixed terminal 2 may also be arranged within 50% of the width L″ of the semiconductor chip (within the width 1″ in FIG. 8, i.e., within 25% of one side), preferably within 20% of the width L″ of the semiconductor chip (i.e., within 10% of one side), more preferably within 10% of the width L″ of the semiconductor chip (i.e., within 5% of one side), with the symmetric line of the semiconductor chip as a center.

Further, as is the case in the first exemplary embodiment, the replaceable terminals may be arranged on a side of the semiconductor chip, the side is vertical to the symmetric line of the semiconductor chip. Further, the replaceable terminals may be arranged at the vicinity of the symmetric line of the semiconductor chip. The vicinity of the symmetric line is within 50% of the width of the semiconductor chip (i.e., within 25% of one side), preferably within 20% of the width of the semiconductor chip (i.e., within 10% of one side), more preferably within 10% of the width of the semiconductor chip (i.e., within 5% of one side), with the symmetric line of the semiconductor chip as a center. In this case, the replaceable terminals may only be arranged at one side of the area divided by the symmetric line.

As mentioned above, in this exemplary embodiment, the fixed terminal is arranged within 50% of the width of the semiconductor chip with the symmetric line of the semiconductor chip as a center. Therefore, it is possible to reduce the variation of the wiring delays of the fixed terminal and to keep the wiring routes from being complicated, when the semiconductor chip is mounted in both the face-up configuration (i.e., WB connection) and the face-down configuration (i.e., FC connection).

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor chip comprising:
a plurality of electrode terminals including a fixed terminal which is supplied with a signal, an outside terminal for the signal being fixed when the semiconductor chip is mounted in both a face-up configuration and a face-down configuration on a package substrate that has the outside terminal, and which is arranged within 50% of the width of the semiconductor chip with a symmetric line of the semiconductor chip as a center.

2. The semiconductor chip according to claim 1, wherein the fixed terminal is arranged within 20% of the width of the semiconductor chip with the symmetric line of the semiconductor chip as a center.

3. The semiconductor chip according to claim 1, wherein the fixed terminal is arranged within 10% of the width of the semiconductor chip with the symmetric line of the semiconductor chip as a center.

4. The semiconductor chip according to claim 1, wherein the fixed terminal is arranged within twenty times of a minimum pitch of the electrode terminals with the symmetric line of the semiconductor chip as a center.

5. The semiconductor chip according to claim 1, wherein the fixed terminal is arranged within twenty times of a minimum pitch of pad electrodes, the package substrate on which the semiconductor chip is mounted includes the pad electrodes, with the symmetric line of the semiconductor chip as a center.

6. The semiconductor chip according to claim 1, wherein the fixed terminal is arranged on the symmetric line of the semiconductor chip.

7. The semiconductor chip according to claim 1, wherein the plurality of electrode terminals include replaceable terminals which are connected to outside terminals and replaceable each other when the semiconductor chip is mounted in both the face-up configuration and the face-down configuration on the package substrate that has the outside terminals, and which are arranged at symmetrical positions with the symmetric line of the semiconductor chip as a center.

8. The semiconductor chip according to claim 1, wherein the plurality of electrode terminals include replaceable terminals which are connected to outside terminals and replaceable each other when the semiconductor chip is mounted in both the face-up configuration and the face-down configuration on the package substrate that has the outside terminals, and which are arranged close to the symmetric line of the semiconductor chip.

9. The semiconductor chip according to claim 1, wherein the plurality of electrode terminals include replaceable terminals which are connected to outside terminals and replaceable each other when the semiconductor chip is mounted in both the face-up configuration and the face-down configuration on the package substrate that has the outside terminals, and which are arranged on a side of the semiconductor chip, the side is vertical to the symmetric line of the semiconductor chip.

10. The semiconductor chip according to claim 1, wherein the symmetric line is a diagonal line of the semiconductor chip.

11. The semiconductor chip according to claim 1, wherein the fixed terminal is a terminal for a high speed signal or a terminal for a control signal.

12. A semiconductor device comprising:
the semiconductor chip according to claim 1;
a package substrate on which the semiconductor chip is mounted and which includes a pad electrode to which the fixed terminal of the semiconductor chip is connected and the outside terminal to which the pad electrode is connected through an internal wiring.

13. The semiconductor device according to claim 12, wherein the pad electrode of the package substrate is arranged close to the symmetric line or on the symmetric line of the semiconductor chip mounted on the package substrate when the semiconductor chip is mounted on the package substrate in the face-up configuration.

14. The semiconductor device according to claim 12, wherein the pad electrode of the package substrate is arranged at a position facing with the fixed terminal of the semiconductor chip mounted on the package substrate when the semiconductor chip is mounted on the package substrate with in face-down configuration.

15. The semiconductor device according to claim 12, wherein a memory chip is mounted on the semiconductor chip, an electrode terminal of the memory chip is connected to a first pad electrode of the package substrate, the fixed terminal of the semiconductor chip is connected to a second pad electrode of the package substrate, and the first pad electrode is connected to the second pad electrode through the internal wiring of the package substrate.
